(19) United States
(12) Patent Application Publication
(10) Pub. No.: US 2026/0040785 A1
(43) Pub. Date: Feb. 5, 2026

(54) DISPLAY DEVICE, ELECTRONIC DEVICE INCLUDING THE SAME, AND INSPECTION METHOD FOR ALIGNMENT OF ELECTRONIC DEVICE

(71) Applicant: SAMSUNG DISPLAY CO., LTD., YONGIN-SI (KR)

(72) Inventors: EUNBYUL KIM, Yongin-si (KR); HANBUM KWON, Yongin-si (KR); YOUNGMIN AHN, Yongin-si (KR); DAEHWAN JANG, Yongin-si (KR)

(21) Appl. No.: 19/267,032

(22) Filed: Jul. 11, 2025

(30) Foreign Application Priority Data
Aug. 1, 2024 (KR) 10-2024-0102646

(51) Int. Cl. H10K 59/131; G06T 7/00; G06T 7/73; H10K 59/95

(52) U.S. Cl. CPC H10K 59/131; G06T 7/0004; G06T 7/73; G06T 2207/30148; H10K 59/95

(57) ABSTRACT

A display device includes a pixel, a signal line electrically connected to the pixel, a signal pad electrically connected to the signal line, an alignment pad spaced apart from the signal pad, and an alignment polymer pattern spaced apart from the alignment pad. The signal pad includes a first conductive pattern electrically connected to an end of the signal line, a conductive polymer pattern disposed on the first conductive pattern, and a second conductive pattern disposed on the conductive polymer pattern.

### CROSS-REFERENCE TO RELATED APPLICATIONS

This patent application claims priority under 35 U.S.C. § 119 to Korean Patent Application No. 10-2024-0102646 filed on Aug. 1, 2024, in the Korean Intellectual Property Office, the disclosure of which is incorporated by reference in its entirety herein.

### 1. Technical Field

Embodiments of the present disclosure are directed to a display device, an electronic device including the same, and an inspection method for alignment of the electronic device. More particularly, the embodiments are directed to a pad area of a display device and an electronic device including the display device.

### 2. Discussion of Related art

Display devices are increasingly utilized across a range of multimedia devices, including televisions, mobile phones, tablet computers, navigation systems, and game consoles. Some of these devices are capable of detecting external inputs through an active display area responsive to electrical signals. Simultaneously, they can display a variety of images to convey information to users.

Examples of these display devices include an Organic Light Emitting Diode (OLED) display device, a Liquid Crystal Display (LCD) device and a MicroLED Display device. OLED displays are known for their superior contrast, color accuracy, and flexibility, making them ideal for high-quality visual experiences in varied device formats. LCDs offer cost-effectiveness and high brightness levels, suited for broad consumer use, including outdoor environments. MicroLED technology provides exceptional brightness and energy efficiency, along with a long lifespan, making it suitable for both small-scale and large-scale advanced display applications.

These display devices typically includes a display panel and a circuit board. Signal pads on these display devices play an important role in facilitating the interface between the display panel and circuit board. The signal pads serve as the connection points for electrical signals between the display panel and the circuit board. These signals may include signals for powering, controlling functions, and transmitting data to the display panel.

During the manufacturing of these display devices, a material may be additionally formed on the signal pads to ensure reliable and durable connections. However, misalignment during the deposition of the material can lead to various issues, impacting the performance, reliability and yield of the display devices. Further, as the shape of the display device becomes more complex, the alignment and deposition processes become more challenging.

### SUMMARY

Embodiments of the present disclosure provide a display device having a structure capable of inspecting positions of polymer patterns of a pad.

Embodiments of the present disclosure provide an electronic device capable of enhancing an alignment inspection quality of a display device and electronic components.

Embodiments of the present disclosure provide an alignment inspection method of an electronic device with increased alignment inspection quality.

According to an embodiment of the present disclosure, a display device includes a pixel, a signal line electrically connected to the pixel, a signal pad electrically connected to the signal line, an alignment pad spaced apart from the signal pad, and an alignment polymer pattern spaced apart from the alignment pad. The signal pad includes a first conductive pattern electrically connected to an end of the signal line, a polymer pattern disposed on the first conductive pattern, and a second conductive pattern disposed on the polymer pattern. The alignment polymer pattern and the polymer pattern may be formed in a same process step.

According to an embodiment, the alignment polymer pattern and the polymer pattern may include the same material.

According to an embodiment, the alignment pad and the alignment polymer pattern may be disposed on the same insulating layer.

According to an embodiment, on a plane, a length of the alignment pad may be greater than or equal to 30 μm and may be shorter than a length of the signal pad.

According to an embodiment, on a plane, a width of the alignment pad may be the same as a width of the signal pad.

According to an embodiment, the alignment pad may be provided as a plurality of alignment pads, and on a plane, the plurality of alignment pads may extend in a first direction and be spaced apart from one another in a second direction intersecting the first direction.

According to an embodiment, the polymer pattern is provided as a plurality of polymer patterns, and on a plane, the plurality of polymer patterns may be spaced apart from each other in the first direction.

According to an embodiment, on a plane, the alignment polymer pattern may be spaced apart from the alignment pad in a first direction, and the alignment pad and the alignment polymer pattern may be spaced apart from the signal pad in a second direction intersecting the first direction. A center of the alignment pad and a center of the alignment polymer pattern may be aligned within the second direction.

According to an embodiment, on a plane, the alignment polymer pattern may be spaced apart from the alignment pad in a first direction, the alignment pad and the alignment polymer pattern may be spaced apart from the signal pad in a second direction intersecting the first direction, and an additional polymer pattern may be further disposed on the alignment pad. A separation distance between the additional polymer pattern and the polymer pattern of the signal pad in the second direction may be the same as a separation distance between the alignment polymer pattern and the polymer pattern of the signal pad in the second direction.

According to an embodiment, the signal pad may be provided as a plurality of signal pads, and the plurality of signal pads may define a plurality of pad rows. Each of the plurality of pad rows may extend in a first direction and may be arranged in a second direction intersecting the first direction, and the signal pads may extend in a first diagonal direction intersecting the first direction and the second direction.

According to an embodiment, the alignment pad may be provided as a plurality of alignment pads, one of the plurality of pad rows may include an alignment inspection area in which the signal pad is not disposed, the plurality of alignment pads may be disposed within the alignment inspection area, and the alignment pads may extend in the first diagonal direction.

According to an embodiment of the present disclosure, an electronic device includes a display device including a display area for displaying an image and a non-display area adjacent to the display area, and an electronic component disposed in the non-display area and electrically connected to the display device. The electronic component includes a signal bump and an alignment bump. The display device includes a pixel disposed in the display area, a signal pad disposed in the non-display area and corresponding to the signal bump, an alignment pad disposed in the non-display area and corresponding to the alignment bump, an alignment polymer pattern disposed in the non-display area and spaced apart from the alignment pad, and a signal line disposed in the display area and the non-display area and electrically connecting the pixel to the signal pad.

According to an embodiment, the signal pad may include a conductive pattern and a polymer pattern protruding toward the signal bump. The polymer pattern and the alignment polymer pattern may be formed using the same process step.

According to an embodiment, the polymer pattern and the alignment polymer pattern may include the same material.

According to an embodiment, the alignment pad may have a smaller area than the signal pad.

According to an embodiment, the alignment pad may expose a portion of the alignment bump.

According to an embodiment, on a plane, the alignment polymer pattern may be spaced apart from the alignment pad in a first direction, and the alignment pad and the alignment polymer pattern may be spaced apart from the signal pad in a second direction intersecting the first direction. An additional polymer pattern may be further disposed on the alignment pad, and a separation distance between the additional polymer pattern and the polymer pattern of the signal pad in the second direction may be the same as a separation distance between the alignment polymer pattern and the polymer pattern of the signal pad in the second direction.

According to an embodiment of the present disclosure, an inspection method for an alignment of an electronic device includes: detecting an alignment inspection area of the electronic device including an alignment bump, an alignment pad bonded to the alignment bump, and an alignment polymer pattern spaced apart from the alignment pad; detecting a center position of the alignment bump, detecting a center position of the alignment pad; detecting a center position of the alignment polymer pattern; comparing at least one of the center position of the alignment bump and the center position of the alignment pad with the center position of the alignment polymer pattern; and determining whether a misalignment has occurred based on a result of the comparing.

According to an embodiment, the electronic device may further include an additional polymer pattern overlapping the alignment pad, and the inspection method may further include calculating a center position of the additional polymer pattern by comparing the center position of the alignment bump with the center position of the alignment polymer pattern.

According to an embodiment, the electronic device may further include an additional polymer pattern overlapping the alignment pad, and the inspection method may further include calculating a center position of the additional polymer pattern by comparing the center position of the alignment pad with the center position of the alignment polymer pattern.

According to an embodiment of the present disclosure, a vision inspection apparatus for detecting misalignment of components within an electronic device includes a camera device and a processor. The camera device is configured to capture images of an alignment inspection area of the electronic device, where the alignment inspection area includes an alignment bump, an alignment pad bonded to the alignment bump, and an alignment polymer pattern that is spaced apart from the alignment pad. The processor is configured to: process the captured images to detect center positions of the alignment bump, the alignment pad, and the alignment polymer pattern; compare the detected center positions of the alignment bump and the alignment pad with the center position of the alignment polymer pattern; and determine presence of misalignment based on results of the compare.

In an embodiment of the vision inspection apparatus, the electronic device further includes an additional polymer pattern overlapping the alignment pad, and the processor is further configured to calculate a center position of the additional polymer pattern by comparing the center position of the alignment bump with the center position of the alignment polymer pattern.

In an embodiment of the vision inspection apparatus, the electronic device further includes an additional polymer pattern overlapping the alignment pad, and the processor is further configured to calculate a center position of the additional polymer pattern by comparing the center position of the alignment pad with the center position of the alignment polymer pattern.

### BRIEF DESCRIPTION OF THE FIGURES

The above and other objects and features of the present disclosure will become apparent by describing in detail embodiments thereof with reference to the accompanying drawings.

FIG. 1 is a coupled perspective view of an electronic device, according to an embodiment of the present disclosure.

FIG. 2 is an exploded perspective view of an electronic device, according to an embodiment of the present disclosure.

FIG. 3 is a cross-sectional view of a display device, according to an embodiment of the present disclosure.

FIG. 4 is a plan view of a display panel, according to an embodiment of the present disclosure.

FIG. 5 is a cross-sectional view of a display panel, according to an embodiment of the present disclosure.

FIG. 6 is an exploded perspective view of an enlarged pad area of a display device, according to an embodiment of the present disclosure.

FIG. 7A is a plan view illustrating a non-display area of a display panel, according to an embodiment of the present disclosure.

FIG. 7B is an enlarged plan view of a part of a non-display area of a display panel, according to an embodiment of the present disclosure.

FIGS. 8A to 8C are each a cross-sectional view of a part of a display panel, according to an embodiment of the present disclosure.

FIG. 9 is a flowchart illustrating an alignment inspection method of an electronic device, according to an embodiment of the present disclosure.

FIGS. 10A to 10C are perspective views illustrating some operations of a method for inspecting alignment of an electronic device, according to an embodiment of the present disclosure.

FIG. 10D is a plan view illustrating some operations of a method for inspecting alignment of an electronic device, according to an embodiment of the present disclosure; and

FIG. 11 is an electronic device, according to an embodiment of the present disclosure.

### DETAILED DESCRIPTION

In the specification, when one component (or area, layer, part, or the like) is referred to as being “on”, “connected to”, or “coupled to” another component, it should be understood that the former may be directly on, connected to, or coupled to the latter, and also may be on, connected to, or coupled to the latter via a third intervening component.

Like reference numerals refer to like components. The term “and/or” includes one or more combinations of the associated listed items. The terms “first”, “second”, etc. are used to describe various components, but the components are not limited by the terms. The terms are used only to differentiate one component from another component. For example, a first component may be named as a second component, and vice versa, without departing from the spirit or scope of the present disclosure. A singular form, unless otherwise stated, includes a plural form.

Also, the terms “under”, “beneath”, “on”, “above” are used to describe a relationship between components illustrated in a drawing. The terms are relative and are described with reference to a direction indicated in the drawing.

It will be understood that the terms “include”, “comprise”, “have”, etc. specify the presence of features, numbers, steps, operations, elements, or components, described in the specification, or a combination thereof, not precluding the presence or additional possibility of one or more other features, numbers, steps, operations, elements, components, or a combination thereof.

Hereinafter, embodiments of the present disclosure will be described with reference to accompanying drawings. The embodiments may provide enhancements in the alignment inspection process for display devices, particularly focusing on the precise placement and inspection of polymer patterns on signal pads. At least one embodiment of the present disclosure introduces an alignment pad and an alignment polymer pattern, which are both strategically spaced apart from the main signal pad. This configuration enables direct verification of the alignment polymer pattern's position on the back surface of the display panel. The alignment can be assessed by comparing the centers of the alignment polymer and the corresponding alignment pad or bump. This approach enhances the alignment inspection quality by allowing more accurate adjustments and ensuring that the polymer patterns on the signal pads are correctly aligned, thereby enhancing the reliability and performance of the display device. Moreover, when the alignment polymer pattern is created using the same materials and process steps as the primary polymer pattern, the manufacturing process may be simplified since additional masks or procedures are not required.

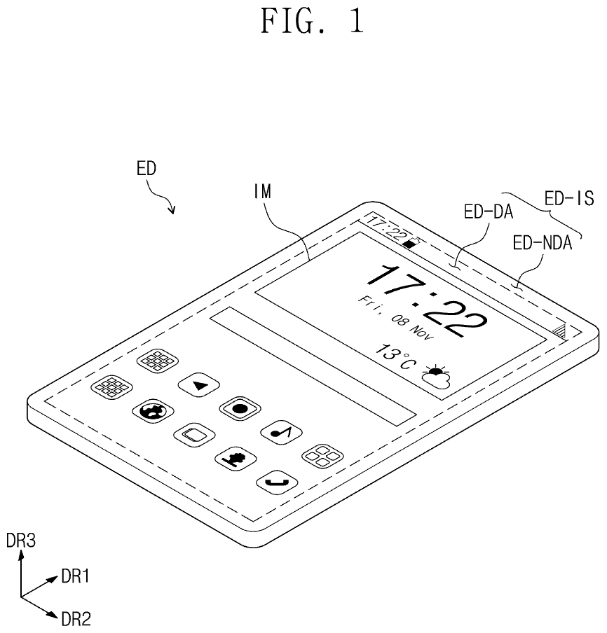

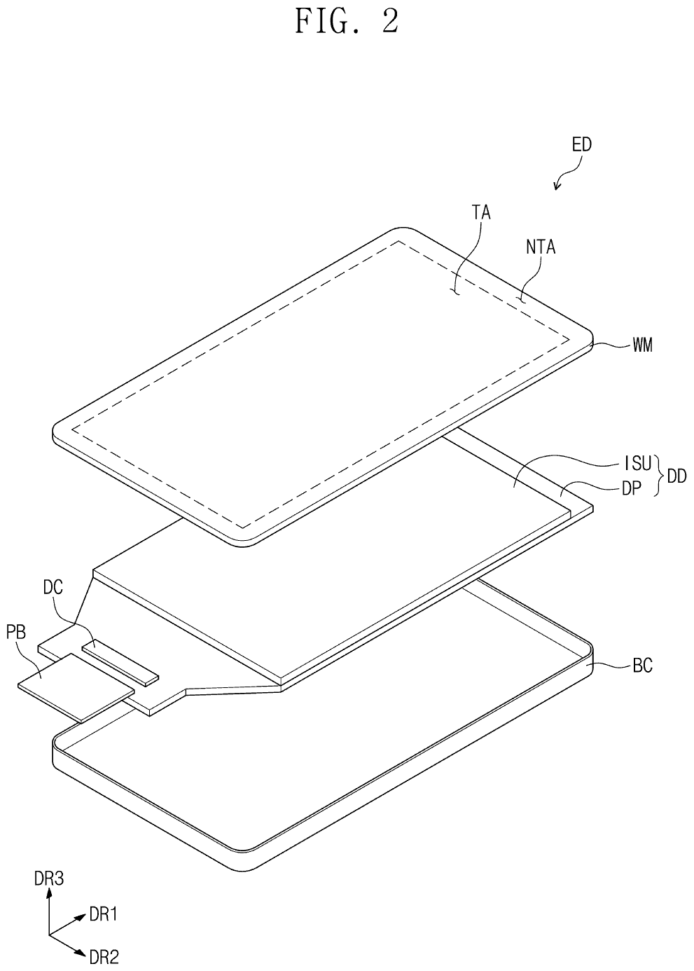

FIG. 1 is a coupled perspective view of an electronic device ED, according to an embodiment of the present disclosure. FIG. 2 is an exploded perspective view of the electronic device ED, according to an embodiment of the present disclosure.

In FIG. 1 and FIG. 2, a mobile phone terminal is illustrated as an example of the electronic device ED. The electronic device ED according to the present disclosure may be applied to large electronic devices such as televisions, monitors, etc., as well as small and medium-sized electronic devices such as tablets, car navigation systems, game consoles, smart watches, etc.

Referring to FIG. 1, the electronic device ED may display an image IM through a display surface ED-IS. Icon images are illustrated as an example of the image IM. The display surface ED-IS is parallel to a surface defined by a first direction DR1 and a second direction DR2. The normal direction of the display surface ED-IS, i.e., the thickness direction of the electronic device ED, is indicated by a third direction DR3. The meaning of “when viewed in a plan view or on a plan view” in this specification may mean a case of viewing from the third direction DR3. Each of the layers or units described below has a front surface (or top surface) and a back surface (or a bottom surface), oriented such that they are separated by the third direction DR3. This third direction DR3, representing the thickness of the electronic device ED, is perpendicular to the display surface ED-IS and defines the vertical arrangement of each component within the electronic device ED.

In addition, the display surface ED-IS includes a display area ED-DA where the image IM is displayed and a non-display area ED-NDA adjacent to the display area ED-DA. The non-display area ED-NDA is an area where the image IM is not displayed. However, the embodiments are not limited thereto, and the non-display area ED-NDA may be adjacent to one side of the display area ED-DA or may be omitted.

Referring to FIG. 2, the electronic device ED may include a window WM, a display device DD, and a housing BC. The housing BC accommodates the display device DD and may be coupled with the window WM. The electronic device ED may further include other electronic modules accommodated in the housing BC and electrically connected to a display panel DP. For example, the electronic device ED may further include a main board, a circuit module mounted on the main board, a camera module, a power module, etc.

The window WM is disposed on the upper side of the display device DD and may transmit an image provided from the display device DD to the outside. The window WM includes a transparent area TA and a non-transparent area NTA. The transparent area TA overlaps the display area ED-DA of FIG. 1 and may have a shape corresponding to the display area ED-DA.

The non-transparent area NTA overlaps the non-display area ED-NDA (refer to FIG. 1) and may have a shape corresponding to the non-display area ED-NDA (refer to FIG. 1). The non-transparent area NTA may have comparatively lower light transmittance than the transparent area TA.

The display device DD may generate an image and may detect an external input. The display device DD includes the display panel DP and an input sensor ISU. The display device DD may further include an anti-reflection member disposed on the input sensor ISU. The anti-reflection member may include a polarizer and a retarder, or a color filter and a black matrix.

According to an embodiment of the present disclosure, the display panel DP may be a light emitting type display panel, but its type is not limited thereto. For example, the display panel DP may be an organic light emitting display panel or an inorganic light emitting display panel. A light emitting layer of the organic light emitting display panel may include an organic light emitting material. A light emitting layer of the inorganic light emitting display panel may include a quantum dot, a quantum rod, a nano LED, etc. Hereinafter, the display panel DP will be described as the organic light emitting display panel.

The input sensor ISU may include any one of a capacitive sensor, an optical sensor, an ultrasonic sensor, and an electromagnetic induction sensor. The input sensor ISU may be formed on the display panel DP through a continuous process, or may be manufactured separately and then attached to the upper side of the display panel DP through an adhesive layer.

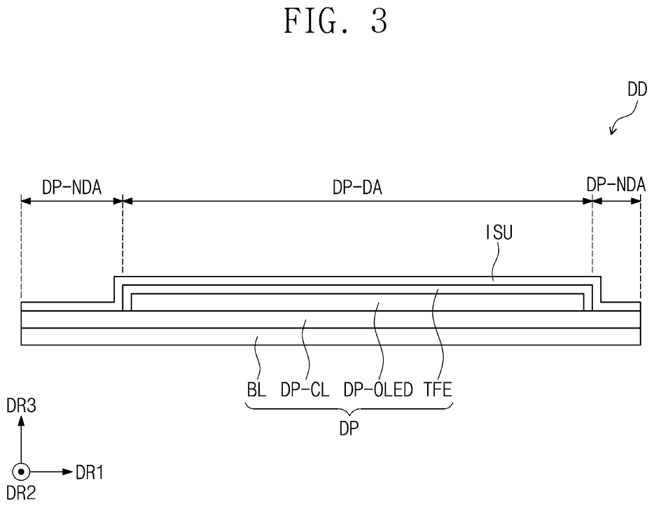

The display device DD of an embodiment may further include a driving chip DC and a circuit board PB. While the driving chip DC is illustrated as being mounted on the display panel DP, the embodiments are not limited thereto. The driving chip DC may generate a driving signal used for the operation of the display panel DP based on a control signal transferred from the circuit board PB. The circuit board PB bonded to the display panel DP may be bent and disposed on a back surface of the display panel DP. The circuit board PB is disposed on one end of a base layer BL (refer to FIG. 3) and may be electrically connected to a circuit element layer DP-CL (refer to FIG. 3).

In the display device DD of an embodiment, a part of the display panel DP may be bent to form a first bent portion such that the driving chip DC faces downward. Further, a part of the non-display area ED-NDA (refer to FIG. 1) of the display panel DP may also be bent to form a second bent portions. However, the bent portions are not limited thereto, and the circuit board PB may be bent.

In the discussion above, while a mobile phone is provided as an example of the electronic device ED, within this specification, any assembly including two or more bonded electronic components may qualify as the electronic device ED. The display panel DP and the driving chip DC mounted on the display panel DP each correspond to different electronic components, and the electronic device ED may be configured with these alone. The electronic device ED may be configured with only the display panel DP and the circuit board PB connected to the display panel DP, and the electronic device ED may be configured with only the main board and the electronic module mounted on the main board. Hereinafter, the electronic device ED according to the present disclosure will be described with a focus on the bonding structure of the display panel DP and the driving chip DC mounted on the display panel DP.

FIG. 3 is a cross-sectional view of a display device DD, according to an embodiment of the present disclosure.

Referring to FIG. 3, the display panel DP may include the base layer BL, the circuit element layer DP-CL disposed on the base layer BL, a display element layer DP-OLED, and a thin film encapsulation layer TFE. The input sensor ISU may be disposed on the thin film encapsulation layer TFE.

The display panel DP includes a display area DP-DA and a non-display area DP- NDA. The display area DP-DA of the display panel DP corresponds to the display area ED-DA illustrated in FIG. 1 or the transparent area TA illustrated in FIG. 2, and the non-display area DP-NDA corresponds to the non-display area ED-NDA illustrated in FIG. 1 or the non-transparent area NTA illustrated in FIG. 2.

The base layer BL may include the display area DP-DA and the non-display area DP-NDA surrounding the display area DP-DA. The base layer BL may include a synthetic resin film. The base layer BL may have a multilayer structure. For example, the base layer BL may have a three-layer structure of a synthetic resin layer, an inorganic layer, and a synthetic resin layer. The synthetic resin layer may be a polyimide-based resin layer, but the material thereof is not limited thereto. The synthetic resin layer may include at least one of acrylate-based resin, methacrylate-based resin, polyisoprene-based resin, vinyl-based resin, epoxy-based resin, urethane-based resin, cellulose-based resin, siloxane-based resin, polyamide-based resin, and perylene-based resin. In addition, the base layer BL may include a glass substrate, a metal substrate, or an organic/inorganic composite material substrate.

The circuit element layer DP-CL may include at least one insulating layer and a circuit element. The insulating layer may include at least one inorganic layer and at least one organic layer. The circuit elements may include signal lines, pixel driving circuits, etc. An insulating layer, a semiconductor layer, and a conductive layer may be formed through processes such as a coating process and/or a deposition process. Afterward, the insulating layer, the semiconductor layer, and the conductive layer may be selectively patterned through photolithography and etching processes. A semiconductor pattern, a conductive pattern, and a signal line may be formed through the above processes. Patterns disposed on the same layer may be formed through the same process. Hereinafter, the fact that the patterns are formed through the same process means that they contain the same material and have the same layered structure.

The display element layer DP-OLED may include an organic light emitting element. The display element layer DP-OLED may further include an organic layer such as a pixel defining film.

The thin film encapsulation layer TFE may be disposed on the circuit element layer DP-CL to cover or encapsulate the display element layer DP-OLED. The thin film encapsulation layer TFE may protect the pixels from moisture, oxygen, and external foreign substances. Additionally, the thin film encapsulation layer TFE is not limited to these functions; it can also incorporate an additional insulating layer beyond the initial encapsulation layer. For example, the thin film encapsulation layer TFE may further include an optical insulating layer for controlling the refractive index.

The input sensor ISU may be directly disposed on the display panel DP. In this specification, “component A is disposed directly on component B” means that an adhesive layer is not disposed between the component “A” and the component “B”. In this embodiment, the input sensor ISU may be manufactured by a continuous process with the display panel DP. However, the technical idea of the present disclosure is not limited thereto, and the input sensor ISU may be provided as a separate panel and then may be combined with the display panel DP through an adhesive layer. According to an embodiment, the input sensor ISU may be omitted.

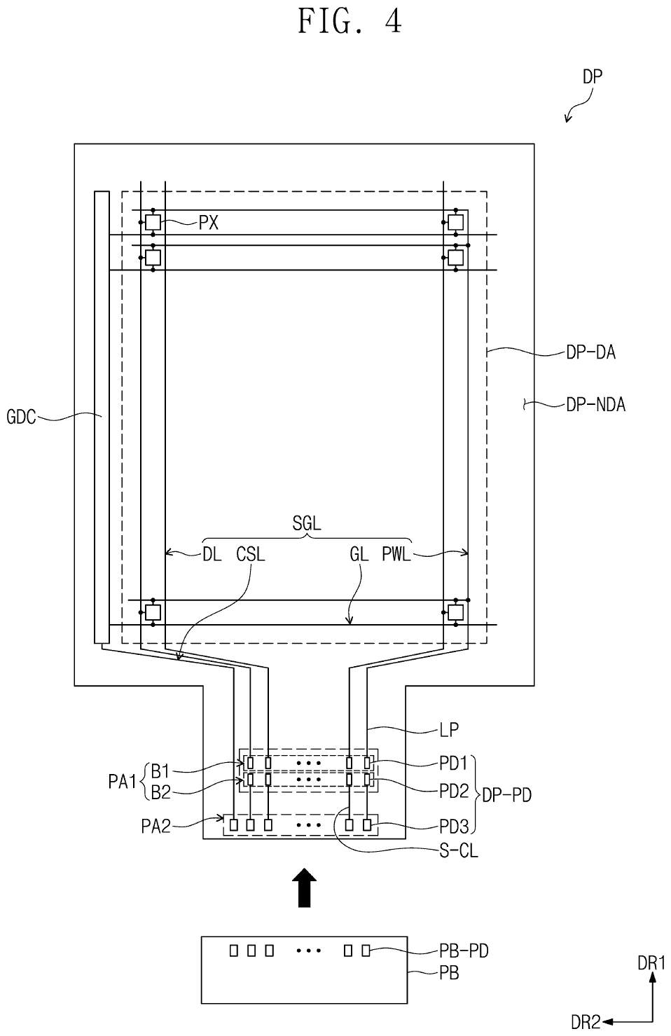

FIG. 4 is a plan view of the display panel DP, according to an embodiment of the present disclosure.

Referring to FIG. 4, the display panel DP may include a plurality of pixels PX, a gate driving circuit GDC, a plurality of signal lines SGL, and a plurality of signal pads DP-PD.

The pixels PX are arranged in the display area DP-DA. Each of the pixels PX includes a light emitting element and a pixel driving circuit connected thereto. The gate driving circuit GDC sequentially outputs gate signals to a plurality of gate lines GL to be described later. A transistor of the gate driving circuit GDC may be formed through the same process as a transistor of the pixel PX, for example, a Low Temperature Polycrystalline Silicon (LTPS) process or a Low Temperature Polycrystalline Oxide (LPTO) process. The display panel DP may further include another driving circuit that provides an emission control signal to the pixels PX.

The signal lines SGL may include the gate lines GL, data lines DL, a power line PWL, and a control signal line CSL. The gate lines GL are respectively connected to a corresponding pixel PX among the pixels PX, and the data lines DL are respectively connected to a corresponding pixel PX among the pixels PX. The power line PWL is connected to the pixels PX. The control signal line CSL is connected to the gate driving circuit GDC and may provide control signals to the gate driving circuit GDC.

The signal lines SGL may overlap the display area DP-DA and the non-display area DP-NDA. Each of the signal lines SGL may include a wiring part LP. The wiring part LP may overlap the non-display area DP-NDA.

The plurality of signal pads DP-PD may include first pads PD1, second pads PD2, and third pads PD3. An area where the first pads PD1 and the second pads PD2 are arranged may be defined as a first pad area PA1, and an area where the third pads PD3 are arranged may be defined as a second pad area PA2.

The first pad area PA1 is an area bonded to the driving chip DC (refer to FIG. 2), and the second pad area PA2 is an area bonded to the circuit board PB (refer to FIG. 2). The first pad area PA1 may include a first area B1 in which the first pads PD1 are arranged and a second area B2 in which the second pads PD2 are arranged. The first pad area PA1 and the second pad area PA2 may be disposed within the non-display area DP-NDA. The first pad area PA and the second pad area PA2 may be spaced apart from each other in the first direction DR1. The first pad area PA1 may be an area adjacent to the display area DP-DA compared to the second pad area PA2, and the second pad area PA2 may be an area spaced apart from the display area DP-DA with the first pad area PA1 interposed therebetween.

Each of the first pads PD1 may be connected to a corresponding data line DL among the data lines DL. The first pads PD1 and the second pads PD2 may be electrically connected to each other. The second pads PD2 may be connected to the third pads PD3 through connection signal lines S-CL.

The circuit board PB may include a plurality of circuit pads PB-PD. The circuit pads PB-PD may be arranged in the second direction DR2. The circuit pads PB-PD on the circuit board PB can establish connections by coming into contact with the third pads PD3 located in the second pad area PA2.

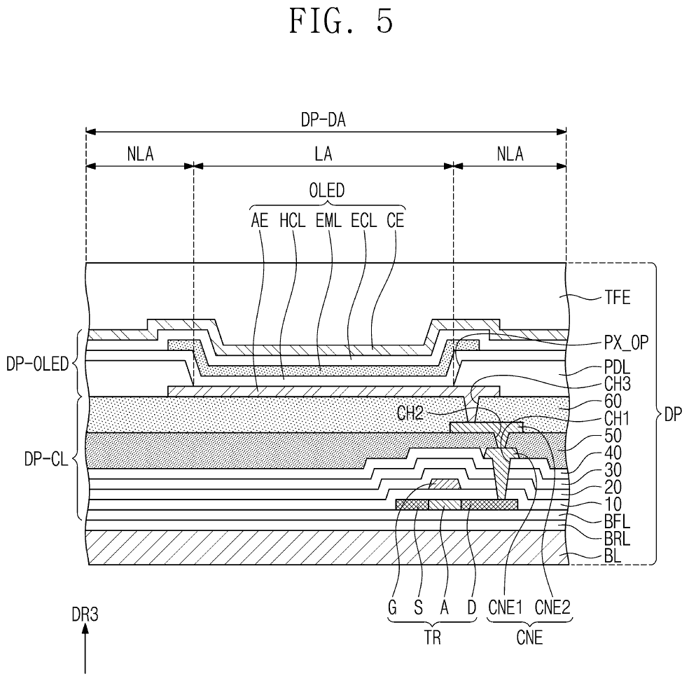

FIG. 5 is a cross-sectional view of the display panel DP, according to an embodiment of the present disclosure.

Referring to FIG. 5, the display panel DP may include the base layer BL, the circuit element layer DP-CL disposed on the base layer BL, the display element layer DP-OLED, and the thin film encapsulation layer TFE.

A plurality of insulating layers are disposed on the upper surface of the base layer BL. The plurality of insulating layers may include a barrier layer BRL and a buffer layer BFL. The plurality of insulating layers may further include a first insulating layer 10, a second insulating layer 20, a third insulating layer 30, a fourth insulating layer 40, a fifth insulating layer 50 and a sixth insulating layer 60. The barrier layer BRL prevents foreign substances from entering from the outside. The barrier layer BRL may include a silicon oxide layer and a silicon nitride layer. These layers may be segmented into multiple pieces, and the silicon oxide layers and the silicon nitride layers may be alternately stacked.

The buffer layer BFL may increase a bonding force between the base layer BL and a semiconductor pattern and/or a conductive pattern. The buffer layer BFL may include a silicon oxide layer and a silicon nitride layer. The silicon oxide layer and the silicon nitride layer of the buffer layer BFL may be alternately stacked.

A semiconductor pattern may be disposed on the buffer layer BFL. The semiconductor pattern may include an amorphous or crystalline silicon semiconductor or a metal oxide semiconductor. The semiconductor pattern may be doped with an N-type dopant or a P-type dopant. The semiconductor pattern may include a highly doped area and a lightly doped area. Conductivity of the highly doped area may be greater than that of the lightly doped area. The highly doped area may function as a source electrode or a drain electrode of a transistor TR. The lightly doped area may serve as an active region (or a channel) of the transistor TR.

A source “S”, an active region “A”, and a drain “D” of the transistor TR may be formed from a semiconductor pattern. The first insulating layer 10 may be disposed on the semiconductor pattern. A gate “G” of the transistor TR may be disposed on the first insulating layer 10. The second insulating layer 20 may be disposed on the gate “G”. The third insulating layer 30 may be disposed on the second insulating layer 20. The fourth insulating layer 40 may be disposed on the third insulating layer 30.

A connection electrode CNE may include a first connection electrode CNE1 and a second connection electrode CNE2, which facilitates the connection between the transistor TR to a light emitting element OLED. The first connection electrode CNE1 may be disposed on the fourth insulating layer 40 and may be connected to the drain D through a first contact hole CH1 defined in the first to fourth insulating layers 10 to 40.

The fifth insulating layer 50 may be disposed on the fourth insulating layer 40. The second connection electrode CNE2 may be disposed on the fifth insulating layer 50. The second connection electrode CNE2 may be connected to the first connection electrode CNE1 through a second contact hole CH2 defined in the fifth insulating layer 50. The second connection electrode CNE2 may be the data line DL of FIG. 4.

The sixth insulating layer 60 may be disposed on the second connection electrode CNE2. Layers from the buffer layer BFL to the sixth insulating layer 60 may be defined as the circuit element layer DP-CL. The first to sixth insulating layers 10 to 60 may be inorganic layers or organic layers.

A first electrode AE may be disposed on the sixth insulating layer 60. The first electrode AE may be connected to the second connection electrode CNE2 through a third contact hole CH3 defined in the sixth insulating layer 60. The first electrode AE may be connected to the transistor TR via the first and second connection electrodes CNE1 and CNE2. A pixel defining film PDL, featuring an opening PX_OP that exposes a specific section of the first electrode AE, may be disposed on the first electrode AE and the sixth insulating layer 60.

A hole control layer HCL may be disposed on the first electrode AE and the pixel defining film PDL. The hole control layer HCL may include a hole transport layer and a hole injection layer.

A light emitting layer EML may be disposed on the hole control layer HCL. The light emitting layer EML may be disposed in an area corresponding to the opening PX_OP. The light emitting layer EML may include an organic material and/or an inorganic material. The light emitting layer EML may generate any one of red, green, and blue light.

An electron control layer ECL may be disposed on the light emitting layer EML and the hole control layer HCL. The electron control layer ECL may include an electron transport layer and an electron injection layer. The hole control layer HCL and the electron control layer ECL may be commonly disposed in both an emission area LA and a non-emission area NLA.

A second electrode CE may be disposed on the electron control layer ECL. The second electrode CE may be commonly disposed or shared across multiple pixels PX (refer to FIG. 4). A layer in which the light emitting element OLED is disposed may be defined as the display element layer DP-OLED.

The thin film encapsulation layer TFE may be disposed on the second electrode CE so as to cover the pixel PX (refer to FIG. 4). The thin film encapsulation layer TFE may include multiple layers. Some of the multiple layers may include an inorganic insulating layer and may protect the pixel PX (refer to FIG. 4) from moisture or oxygen. Some of the remaining layers may include an organic insulating layer and may protect the pixel PX (refer to FIG. 4) from foreign substances such as dust particles.

A first voltage may be applied to the first electrode AE through the transistor TR, and a second voltage having a level lower than the first voltage may be applied to the second electrode CE. Excitons may be formed by coupling holes and electrons injected into the light emitting layer EML. As the excitons transition to a ground state, the light emitting element OLED may emit light.

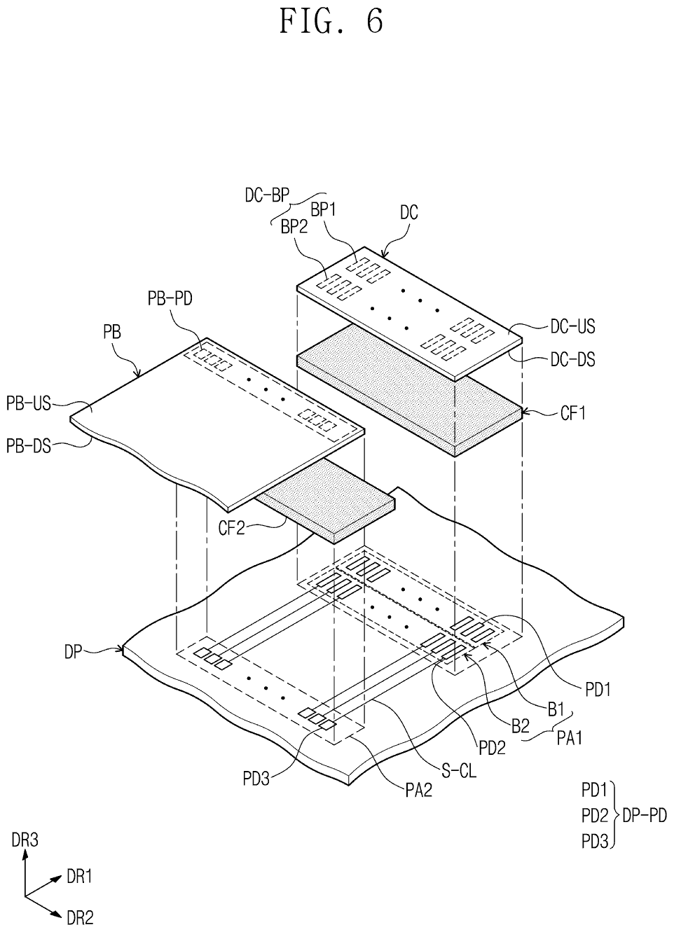

FIG. 6 is an exploded perspective view of enlarged pad areas PA1 and PA2 of the display device DD, according to an embodiment of the present disclosure. For example, in FIG. 6, the driving chip DC and the circuit board PB are illustrated as being disassembled from the display panel DP. Since the first pads PD1, the second pads PD2, the connection signal lines S-CL, and the third pads PD3 of FIG. 6 are the same as those of FIG. 4, additional description thereof will be omitted to avoid redundancy.

The driving chip DC may be bonded to the first pad area PA1 through a first adhesive layer CF1, and the circuit board PB may be bonded to the second pad area PA2 through a second adhesive layer CF2.

According to an embodiment of the present disclosure, the first adhesive layer CF1 and the second adhesive layer CF2 are non-conductive films. In an embodiment, the first adhesive layer CF1 and the second adhesive layer CF2 do not include a conductive ball and include a synthetic resin having adhesive properties. In this embodiment, the synthetic resin does not need to maintain the arrangement of conductive balls, so the synthetic resin may have relatively low viscosity.

When the first adhesive layer CF1 is cured, the first pads PD1 and first bumps BP1 may be fixed in a state of contact, and the second pads PD2 and second bumps BP2 may be fixed in a state of contact. In addition, when the second adhesive layer CF2 is cured, the third pads PD3 and circuit pads PB-PD may be fixed in a state of contact.

The driving chip DC may include a driving integrated circuit and chip bumps DC-BP mounted in the driving chip DC. The driving chip DC may include an upper surface DC-US and a lower surface DC-DS, and the lower surface DC-DS may be a surface facing the first pad PD1 and the second pad PD2. The chip bumps DC-BP may be disposed on the lower surface DC-DS of the driving chip DC.

The chip bumps DC-BP may include the first bumps BPI electrically connected to the first pads PD1, respectively, and the second bumps BP2 electrically connected to the second pads PD2, respectively. The first bumps BPI may be arranged along the second direction DR2, and the second bumps BP2 may be spaced apart from the first bumps BP1 in the first direction DR1 and may be arranged along the second direction DR2.

The driving chip DC may receive first signals from the outside through the second pads PD2 and the second bumps BP2. The driving chip DC may provide second signals generated based on the first signals to the first pads PD1 through the first bumps BP1. For example, the driving chip DC may include a data driving circuit. The first signal may be an image signal, which is a digital signal applied from the outside, and the second signal may be a data signal, which is an analog signal. The driving chip DC may generate an analog voltage corresponding to the grayscale value of the image signal. The data signal may be provided to the pixel PX through the data line DL illustrated in FIG. 4.

In FIG. 6, for convenience of description, the planar shape of the chip bumps DC-BP is illustrated as a dotted line on the upper surface DC-US of the driving chip DC, but each of the first bumps BP1 and the second bumps BP2 may be shaped to protrude from the lower surface DC-DS of the driving chip DC and may be exposed to the outside.

The circuit board PB may be disposed on the display panel DP. The circuit board PB may be disposed on the third pads PD3. The circuit board PB may include a top surface PB-US and a bottom surface PB-DS, and the bottom surface PB-DS may be a surface facing the third pads PD3. The circuit board PB may include a plurality of circuit pads PB-PD electrically connected to the third pads PD3. The circuit pads PB-PD may be disposed on the top surface PB-US of the circuit board PB. The circuit pads PB-PD may be arranged in the second direction DR2. The circuit board PB may provide an image signal, a driving voltage, and other control signals to the driving chip DC.

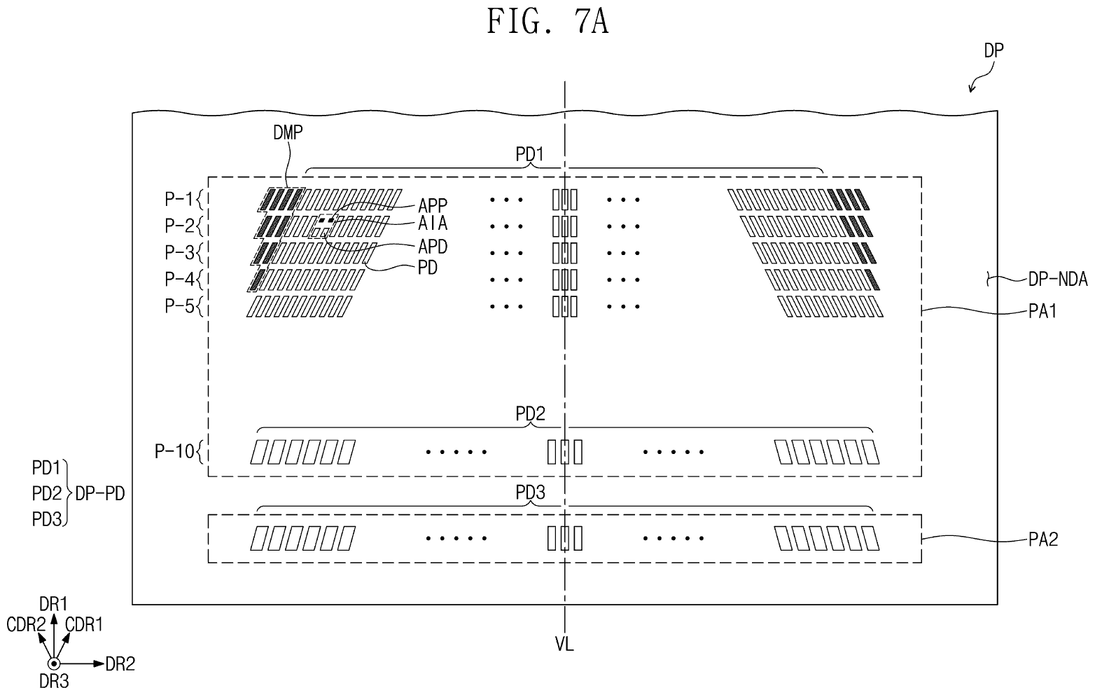

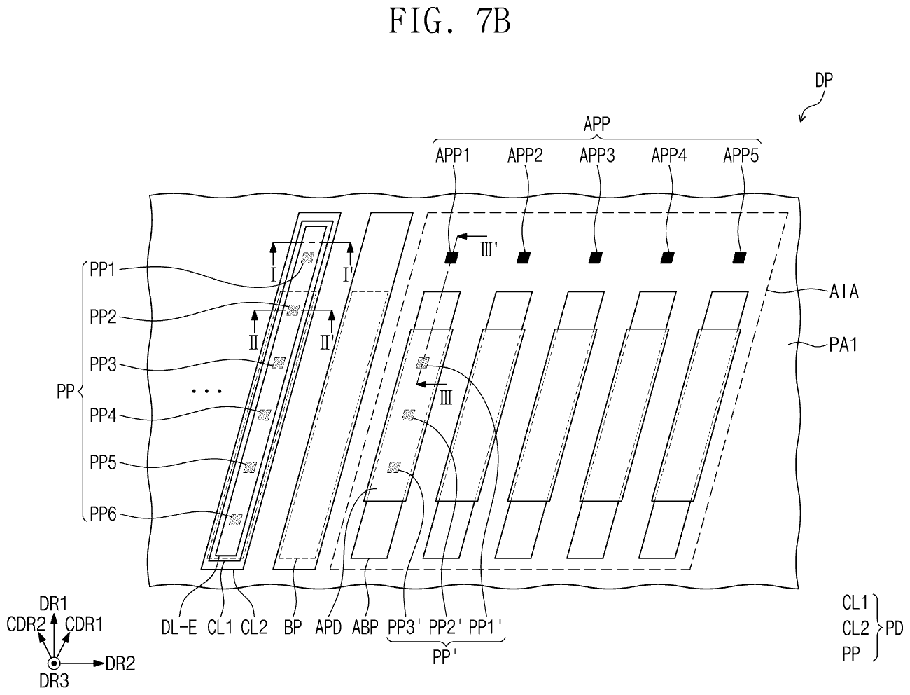

FIG. 7A is a plan view illustrating the non-display area DP-NDA of the display panel DP, according to an embodiment of the present disclosure. FIG. 7B is an enlarged plan view of a part of the non-display area DP-NDA of the display panel DP, according to an embodiment of the present disclosure.

In FIG. 7A, the first pad area PAI and the second pad area PA2 illustrated in FIG. 6 are enlarged. The driving chip DC (refer to FIG. 6) is bonded to the first pad area PA1, and the circuit board PB (refer to FIG. 6) is bonded to the second pad area PA2. The description of the first pad area PA1 may be equally applied to the second pad area PA2, and the description of the first pads PD1 and the second pads PD2 may be equally applied to the third pads PD3. Each of the pads arranged in the first pad area PAI and the second pad area PA2 may be referred to as a signal pad PD electrically connected to the data line DL (refer to FIG. 4). In detail, the signal pad

PD may mean each of the remaining pads other than an alignment pad APD and dummy pads DMP arranged in an alignment inspection area AIA described below.

The first pads PD1 may define a plurality of input rows P-1, P-2, P-3, P-4, and P-5 each extending in the second direction DR2. The second pads PD2 may define an output row P-10.

A first center pad disposed at the center of the second direction DR2 among the first pads PD1 and a second center pad disposed at the center of the second direction DR2 among the second pads PD2 may be positioned on a reference line VL.

The first pads PD1 disposed on the left side of the reference line VL among the

first pads PD1 are positioned to have a preset inclination with respect to the reference line VL. The first pads PD1 disposed on the left side may extend in a first diagonal direction CDR1 intersecting the first direction DR1 and the second direction DR2. Among the first pads PD1, the first pads PD1 disposed on the right side of the reference line VL may extend in a second diagonal direction CDR2 symmetrical to the first diagonal direction CDR1 with respect to the first direction DR1. For example, the first pads PD1 to the left and right of the reference line VL may be arranged in a diagonal direction.

The second pads PD2 disposed on the output row P-10 may also include the second pads PD2 disposed on the left side and the second pads PD2 disposed on the right side, which are distinguished by the reference line VL.

The dummy pads DMP may be further disposed in the first pad area PA1. The dummy pads DMP may be disposed on the outermost side of the first pad area PA1 in the second direction DR2. The dummy pads DMP may be formed through the same process as the first pads PD1 and the second pads PD2, and may include the same materials. Each of the dummy pads DMP may be electrically isolated pads. For example, while the first pads PD1 may be electrically connected to the data lines DL, the dummy pads DMP are not electrically connected to the data line DL.

The alignment inspection area AIA may be disposed in some of the input rows P-1, P-2, P-3, P-4, and P-5 disposed in the first pad area PA1. The alignment inspection area AIA is formed in an area where the first pads PD1 are not disposed among the input rows P-1, P-2, P-3, P-4, and P-5. For example, when forming the first pads PD1, this area may be skipped so that the alignment inspection area AIA may be formed. The alignment pad APD and an alignment polymer pattern APP are disposed in the alignment inspection area AIA. In FIG. 7A, the alignment inspection area AIA disposed in the second input row P-2 is illustrated as an example, but the input rows are not limited thereto. For example, the alignment inspection area AIA could be disposed in any of the input rows. In addition, although two of the alignment pads APD and two of the alignment polymer patterns APP are illustrated in the alignment inspection area AIA of FIG. 7A, the number of pads or patterns is not limited thereto. In addition, the alignment inspection area AIA may be further disposed on the right side of the reference line VL. For example, some of the first pads PD1 to the right of the reference line VL could be replaced with the alignment inspection area AIA in one or more of the input rows.

In an embodiment, the alignment pad APD is formed through the same process as the signal pad PD and has the same thickness. The alignment pad APD may be spaced apart from the signal pad PD in the second direction DR2. In addition, the alignment polymer pattern APP may be spaced apart from the signal pad PD in the second direction DR2 and may be spaced apart from the alignment pad APD in the first direction DR1.

FIG. 7B is a plan view of the alignment inspection area AIA disposed in a part of the first pad area PA1 and the signal pads PD adjacent to the alignment inspection area AIA as viewed in the third direction DR3 from the back surface of the display panel DP. In FIG. 7B, the data line DL (refer to FIG. 4) including an end portion DL-E is illustrated as an example of a signal line, but the signal line is not limited thereto. For convenience, only the end portion DL-E of the data line DL (refer to FIG. 4) is illustrated. For example, the configurations disposed on the signal pad PD and the configurations disposed on the alignment pad APD need not actually be observed on the back surface of the display panel DP and may be illustrated for convenience of description. Hereinafter, the signal pad PD on which the data line DL (refer to FIG. 4) is disposed will be described.

The signal pad PD may include a first conductive pattern CL1, a second conductive pattern CL2, and a polymer pattern PP. The first conductive pattern CL1 may be connected to the end portion DL-E of the data line DL (refer to FIG. 4) through at least one contact hole. In FIG. 7B, one signal pad PD is illustrated as including six polymer patterns PP1 to PP6, but the number of polymer patterns PP is not limited thereto.

On a plane, the end portion DL-E may have a shape extending in the first direction DR1. The length of the end portion DL-E in the first direction DR1 may be greater than the length in the second direction DR2.

On a plane, the polymer patterns PP may overlap the first conductive pattern CL1 and the second conductive pattern CL2. The polymer patterns PP may be arranged along the first direction DR1. The polymer patterns PP may be spaced apart from each other within the first direction DR1.

In FIG. 7B, the polymer patterns PP are illustrated as being square, but are not limited thereto. For example, the shape of the polymer patterns PP on the plane may be changed to a rectangle, a polygon other than a square, a rectangle, a circle, an oval, etc. In addition, the shape of the polymer patterns PP is not limited to being the same.

On the plane, the second conductive pattern CL2 may have an area greater than the first conductive pattern CL1, and the first conductive pattern CL1 may be disposed inside the second conductive pattern CL2.

The alignment pad APD and the alignment polymer pattern APP are disposed in the alignment inspection area AIA. A plurality of alignment pads APD are provided, and each of the plurality of alignment pads APD may extend in the first direction DR1 and the plurality of alignment pads APD may be spaced apart from each other in the second direction DR2. In addition, each of the plurality of alignment pads APD may extend in the first diagonal direction CDR1.

As illustrated in FIG. 7B, the length of the alignment pad APD in the first direction DR1 on the plane may be shorter than the length of the signal pad PD in the first direction DR1. For example, the length of the alignment pad APD in the first direction DR1 may be 30 micrometers (um) or more (e.g., greater than or equal to 30 μm). For alignment measurement with an alignment bump ABP, the length of the alignment pad APD in the first direction DR1 may be shorter than the length of the alignment bump ABP in the first direction DR1. Therefore, the alignment pad APD may have a smaller area than the signal pad PD.

The length of the alignment pad APD in the second direction DR2 may be the same as the length of the signal pad PD in the second direction DR2. In an embodiment, a width of the alignment pad APD is the same as a width of the signal pad PD. Accordingly, the width at which the signal pad PD and a bump BP are bonded may be the same as the width at which the alignment pad APD and the alignment bump ABP are bonded.

On the plane, a polymer pattern PP′ (e.g., may be referred to as an additional polymer pattern) may be further disposed on the alignment pad APD. The alignment pad APD may further include the first conductive pattern CL1 and the second conductive pattern CL2. The polymer pattern PP′ disposed on the alignment pad APD may include the same material as the polymer pattern PP of the signal pad PD and may be formed in the same process. In addition, a plurality of polymer patterns PP1′ to PP3′ may be spaced apart from each other along the first direction DR1. However, the present disclosure is not limited thereto. For example, the first and second conductive patterns CL1 and CL2 and the polymer pattern PP′ may not be disposed in the alignment inspection area AIA where the alignment pad APD is disposed.

In an embodiment of the present disclosure, a plurality of alignment polymer patterns APP are provided. For example, the plurality of alignment polymer patterns APP may include a plurality of alignment polymer patterns APP1 to APP5 disposed corresponding to the alignment pad APD, respectively. The plurality of alignment polymer patterns APP1 to APP5 may be spaced apart from each other in the second direction DR2.

The centers of the alignment pad APD and the alignment polymer pattern APP may be aligned in the second direction DR2. In an embodiment, the center of the alignment pad APD in the second direction DR2 is disposed identically to the center of the corresponding alignment polymer pattern APP in the second direction DR2. In the present disclosure, the center may mean the center position of the alignment pad APD or the alignment polymer pattern APP in the second direction DR2 when viewed on a plane.

In addition, the separation distance between the polymer pattern PP′ of the alignment pad APD and the polymer pattern PP of the signal pad PD in the second direction DR2 may be the same as the separation distance between the alignment polymer pattern APP and the polymer pattern PP of the signal pad PD in the second direction DR2. Accordingly, the position information of the alignment pad APD measured within the alignment inspection area AIA may also be applied to the signal pad PD.

In an embodiment, the alignment polymer pattern APP is formed using the same process step as the polymer pattern PP disposed on the signal pad PD. Therefore, the alignment polymer pattern APP may be easily formed by patterning alone without an additional mask. In an embodiment, the alignment polymer pattern APP has the same size as the polymer pattern PP and includes the same material.

Referring to FIG. 7B, the bump BP and the alignment bump ABP may be included in the chip bumps DC-BP (refer to FIG. 6). In FIG. 7B, the bump BP may mean a signal bump bonded to the signal pad PD, and the alignment bump ABP may mean a bump bonded to the alignment pad APD. The bump BP and the alignment bump ABP may also extend in the first direction DR1 and may be spaced apart in the first diagonal direction CDR1. Additionally, the length and width of the bump BP and the alignment bump ABP may also be the same, and the description of the separation distance may also be applied equally.

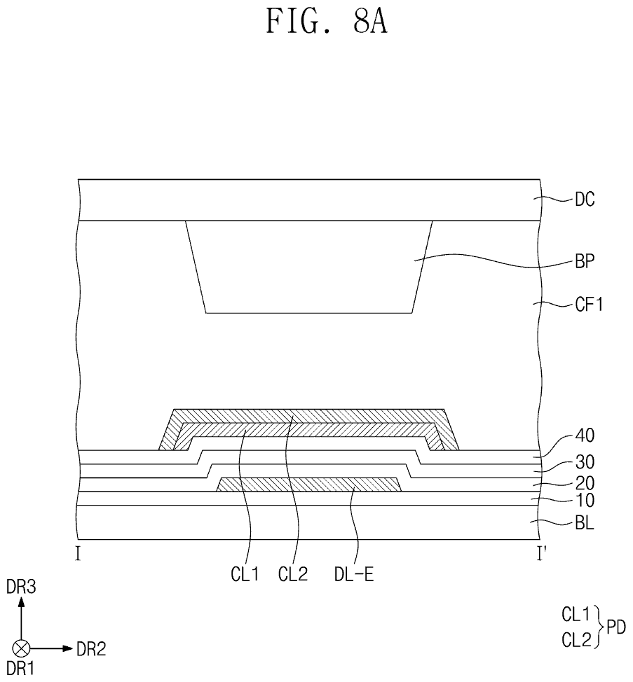

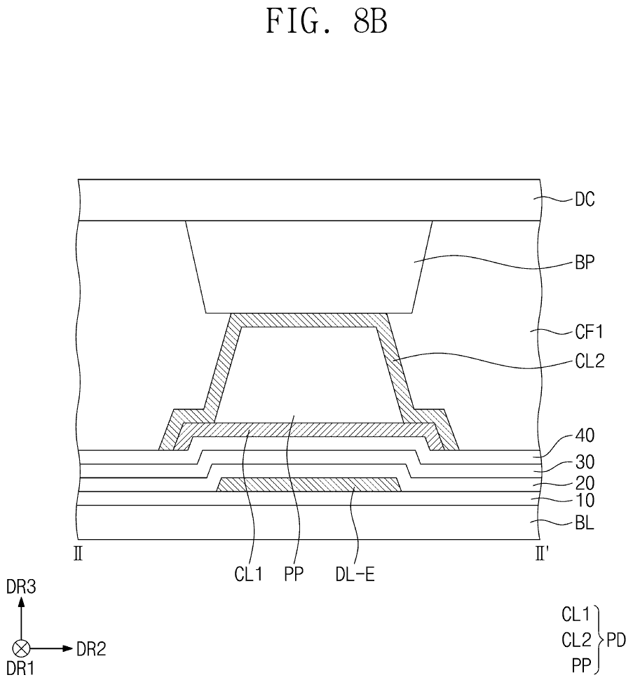

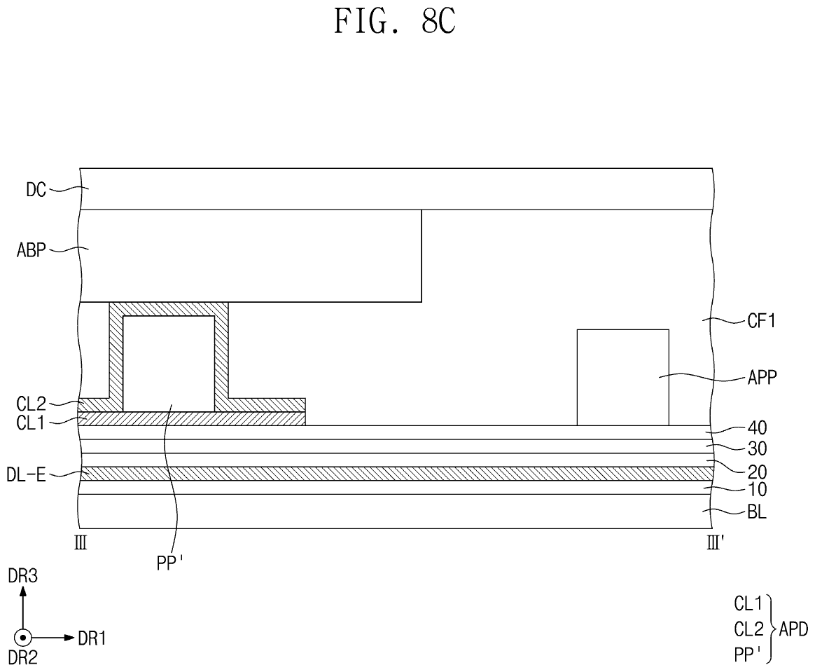

FIGS. 8A to 8C are each a cross-sectional view of a part of a display panel, according to an embodiment of the present disclosure.

FIG. 8A illustrates a cross-section corresponding to an I-I′ cut line of FIG. 7B, FIG. 8B illustrates a cross-section corresponding to a II-II′ cut line of FIG. 7B, and FIG. 8C illustrates a cross-section corresponding to a III-III′ cut line of the alignment inspection area AIA of FIG. 7B.

In FIGS. 8A to 8C, a description of the configuration described above in the description of FIG. 5 may be omitted. In an embodiment, the barrier layer BRL (refer to FIG. 5) and the buffer layer BFL (refer to FIG. 5) are further included between the base layer BL and the first insulating layer 10 in FIGS. 8A to 8C.

Referring to FIG. 8A, the end portion DL-E may be disposed on the first insulating layer 10. The end portion DL-E may be disposed at the same layer as the gate “G” (refer to FIG. 5). The end portion DL-E may be formed through the same process as the gate “G” (refer to FIG. 5) and may include the same material. However, the position of the end portion DL-E is not limited thereto.

The first conductive pattern CL1 may be disposed on the fourth insulating layer 40. The first conductive pattern CL1 may be connected to the end portion DL-E through the first contact hole CH1 (refer to FIG. 5) penetrating the second to fourth insulating layers 20, 30, and 40. In detail, the first conductive pattern CL1 may be in contact with the end portion DL-E through the first contact hole CHI (refer to FIG. 5). The first conductive pattern CL1 and the end portion DL-E may be distinguished by the second to fourth insulating layers 20, 30, and 40 disposed therebetween.

Referring to FIGS. 8A and 8B, the second conductive pattern CL2 may be disposed on the first conductive pattern CL1. In an embodiment, an area of the second conductive pattern CL2 that does not overlap with the polymer pattern PP is in contact with the first conductive pattern CL1. An area of the second conductive pattern CL2 that overlaps with the polymer pattern PP may be in contact with the polymer pattern PP.

In an embodiment, the first conductive pattern CL1 may be formed through the same process as the first connection electrode CNE1 (refer to FIG. 5), and the second conductive pattern CL2 may be formed through the same process as the second connection electrode CNE2 (refer to FIG. 5). The first conductive pattern CL1 may include the same material as the first connection electrode CNE1 (refer to FIG. 5), and the second conductive pattern CL2 may include the same material as the second connection electrode CNE2 (refer to FIG. 5). In FIGS. 8A to 8C, an embodiment in which the first conductive pattern CL1 is disposed on the fourth insulating layer 40 is illustrated as an example, but depending on the embodiment, the first conductive pattern CL1 may be disposed on the third insulating layer 30, and the fourth insulating layer 40 may be omitted. However, the present disclosure is not limited thereto, and the combination of connection electrodes formed through the same process as the first and second conductive patterns CL1 and CL2 may be variously selected depending on the stacked structure of the circuit element layer DP-CL (refer to FIG. 5) as long as the first and second conductive patterns CL1 and CL2 of different layers are provided.

Referring to FIG. 8B, the polymer pattern PP may be disposed between the first conductive pattern CL1 and the second conductive pattern CL2. The polymer pattern PP may be disposed on the first conductive pattern CL1 and may be covered by the second conductive pattern CL2. In an embodiment, the polymer pattern PP includes a thermosetting polymer. However, the present disclosure is not limited thereto. For example, the polymer pattern PP may include a thermoplastic polymer.

Referring to FIGS. 8A and 8B, the bump BP may be disposed on the lower portion of the driving chip DC, and the driving chip DC may be bonded to the signal pad PD through the first adhesive layer CF1. As illustrated in FIG. 8B, some of the bumps BP may be electrically connected to the second conductive pattern CL2 of the signal pad PD through a contact. In particular, the polymer pattern PP is disposed on the first conductive pattern CL1, so that the second conductive pattern CL2 may protrude toward the driving chip DC. In detail, the polymer pattern PP may protrude in the third direction DR3 toward the second conductive pattern CL2 and the bump BP, and the second conductive pattern CL2 may also protrude in the third direction DR3 to come into contact with the bump BP. Accordingly, the electronic device ED of the present disclosure may bond the driving chip DC and the display panel DP through a non-conductive film (e.g., the first adhesive layer CF1) without conductive particles such as conductive balls. Therefore, even if the display panel DP and the driving chip DC become misaligned, a short circuit defect caused by conductive particles such as conductive balls may be prevented, so that electrical characteristics may be enhanced.

FIG. 8C illustrates a cross-section of the alignment pad APD and the alignment polymer pattern APP disposed in the alignment inspection area AIA. The alignment pad APD, like the signal pad PD, may include the first conductive pattern CL1, the second conductive pattern CL2, and the polymer pattern PP′. Accordingly, the second conductive pattern CL2 may be electrically connected to the alignment bump ABP through a contact. However, the embodiments are not limited thereto. For example, some of the first conductive pattern CL1, the second conductive pattern CL2, and the polymer pattern PP′ included in the alignment pad APD may be omitted. For example, the first conductive pattern CL1 or the polymer pattern PP′ may be omitted from the alignment pad APD so that the alignment pad APD does not make contact with the alignment bump ABP.

The alignment pad APD and the alignment polymer pattern APP may be disposed on the fourth insulating layer 40. The alignment pad APD and the alignment polymer pattern APP may be disposed on the same insulating layer.

In an embodiment, the alignment pad APD overlaps the alignment bump ABP and exposes a portion of the alignment bump ABP. That is, a side of the alignment bump ABP does not overlap with the alignment pad APD, so that the alignment bump ABP may be partially exposed. Accordingly, when viewed from the back surface of the display panel DP (refer to FIG. 7B), the portion of the alignment bump ABP exposed from the alignment pad APD may be observed.

However, on the back surface of the display panel DP (refer to FIG. 7B), it may only be observed that the alignment pad APD overlaps or exposes part of the alignment bump ABP, and a specific overlapping position of the polymer pattern PP′ of the alignment pad APD and the alignment bump ABP may not be directly observable.

In contrast, the alignment polymer pattern APP may be non-overlapping with the alignment bump ABP. Accordingly, the positions of the alignment polymer patterns APP may be directly observable on the back surface of the display panel DP (refer to FIG. 7B). That is, only the positions of the alignment pad APD, the alignment bump ABP, and the alignment polymer pattern APP may be observable on the back surface of the display panel DP (refer to FIG. 7B).

When the center of the polymer pattern PP′ of the alignment pad APD in the second direction DR2 is patterned identically to the center of the alignment polymer pattern APP in the second direction DR2, the position of the center of the polymer pattern PP′ in the second direction DR2 may be derived from the position of the center of the alignment polymer pattern APP in the second direction DR2.

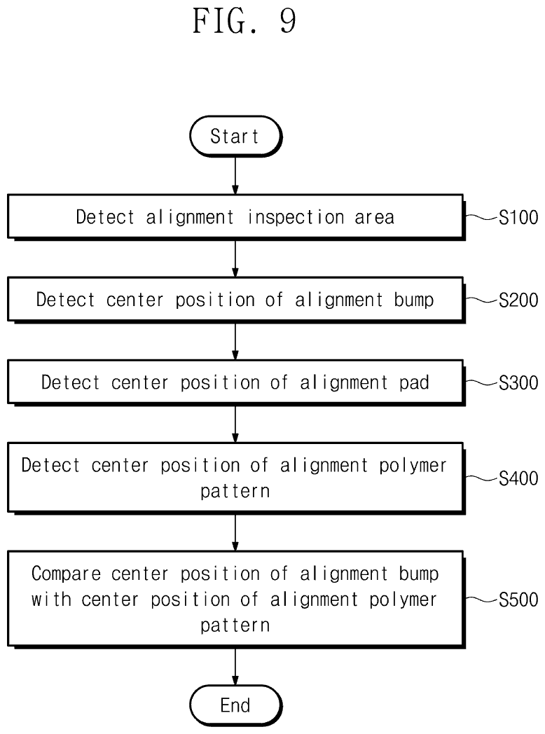

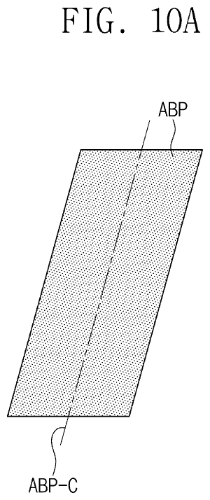

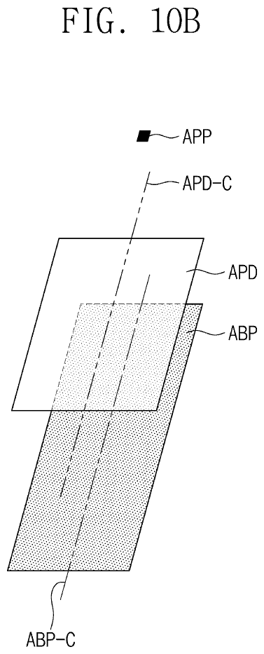

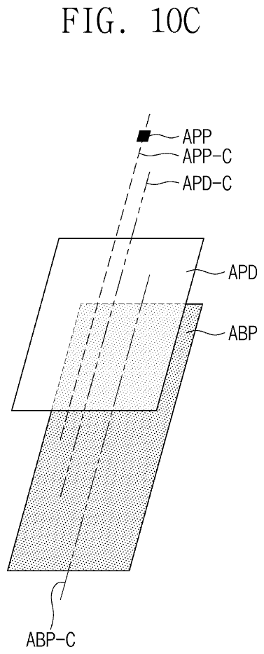

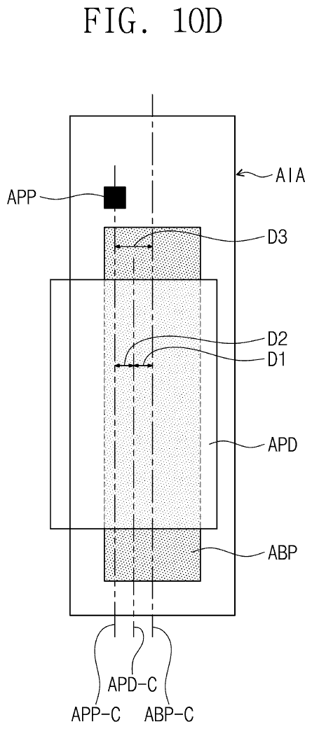

FIG. 9 is a flowchart illustrating an alignment inspection method of an electronic device, according to an embodiment of the present disclosure. FIGS. 10A to 10C are perspective views illustrating some operations of a method for inspecting alignment of an electronic device, according to an embodiment of the present disclosure, and FIG. 10D is a plan view illustrating some operations of a method for inspecting alignment of an electronic device, according to an embodiment of the present disclosure. The contents and configurations described above in FIGS. 6 to 8C may be applied equally to FIGS. 9 and 10A to 10D.

Referring to FIG. 9, an alignment inspection method of an electronic device includes operation S100 of detecting an alignment inspection area, operation S200 of detecting a center position of an alignment bump, operation S300 of detecting a center position of an alignment pad, operation S400 of detecting a center position of an alignment polymer pattern, and operation S500 of comparing at least one of the center position of the alignment bump and the center position of the alignment pad with the center position of the alignment polymer pattern.

In operation S100 of detecting the alignment inspection area AIA, a vision inspection machine (e.g., vision inspection apparatus) may be used. The alignment inspection area AIA may be detected using the vision inspection machine. As described above, the alignment inspection area AIA includes the alignment bump ABP, the alignment pad APD bonded to the alignment bump ABP, and the alignment polymer pattern APP that is non-overlapping with the alignment pad APD. The vision inspection machine may include a camera device, and the camera device may detect the position of the alignment inspection area AIA on the back surface of the display panel DP illustrated in FIG. 6.

FIGS. 10A to 10D illustrate one of the alignment bump ABP, an alignment pad APD, and the alignment polymer pattern APP disposed within the alignment inspection area AIA, as an example. FIGS. 10A to 10D illustrate detection of the position of the alignment inspection area AIA on the back surface of the display panel DP illustrated in FIG. 7B.

FIG. 10A is a perspective view illustrating operation S200 of detecting the center position of the alignment bump ABP of FIG. 9. The alignment status of the alignment bump ABP may be detected using the vision inspection machine. A center position ABP-C of the alignment bump ABP may intersect a virtual extension line of FIG. 10A drawn at the center of the width of the alignment bump ABP.

FIG. 10B is a perspective view illustrating operation S300 of detecting the center position of the alignment pad APD of FIG. 9. The alignment status of the alignment pad APD may be detected using the vision inspection machine. A center position APD-C of the alignment pad APD may intersect a virtual extension line of FIG. 10B drawn at the center of the width of the alignment pad APD. The center position APD-C of the alignment pad APD may be parallel to the center position ABP-C of the alignment bump ABP.

FIG. 10C is a perspective view illustrating operation S400 of detecting the center position of the alignment polymer pattern APP of FIG. 9. The alignment status of the alignment polymer pattern APP may be detected using the vision inspection machine. A center position APP-C of the alignment polymer pattern APP may intersect a virtual extension line of FIG. 10C drawn at the center of the width of the alignment polymer pattern APP. The center position APP-C of the alignment polymer pattern APP may be parallel to the center position APD-C of the alignment pad APD and the center position ABP-C of the alignment bump ABP.

FIG. 10D is a plan view illustrating operation S500 of comparing the center position APP-C of the alignment polymer pattern APP with at least one of the center position ABP-C of the alignment bump ABP and the center position APD-C of the alignment pad APD in FIG. 9.

The difference between the center position ABP-C of the alignment bump ABP and the center position APD-C of the alignment pad APD may be measured as a first distance D1, the difference between the center position APD-C of the alignment pad APD and the center position APP-C of the alignment polymer pattern APP may be measured as a second distance D2, and the difference between the center position ABP-C of the alignment bump ABP and the center position APP-C of the alignment polymer pattern APP may be measured as a third distance D3.

As the first distance D1, the second distance D2, and the third distance D3 all approach “0”, it may be determined that the alignment bump ABP, the alignment pad APD, and the alignment polymer pattern APP are becoming more aligned. The third distance D3 is the sum of the first distance DI and the second distance D2, and may be used to determine the actual alignment of the alignment bump ABP and the alignment polymer pattern APP. In detail, the alignment degree of the polymer pattern PP of the actual signal pad PD and the signal bump may be measured by comparing the center position APP-C of the alignment polymer pattern APP with the center position ABP-C of the alignment bump ABP.

In addition, referring to FIG. 7B, the polymer pattern PP′ overlapping the alignment pad APD illustrated in FIG. 7B may be further included. In addition, when it is assumed that the center position APP-C of the alignment polymer pattern APP is the same as the center position of the polymer pattern PP′, the center position of the polymer pattern PP′ may be calculated by the third distance D3 that is obtained by comparing the center position ABP-C of the alignment bump ABP with the center position APP-C of the alignment polymer pattern APP. Accordingly, the alignment degree of the polymer pattern PP′ of the alignment pad APD and the alignment bump ABP may be measured.

In an embodiment, the center position of the polymer pattern PP′ may be calculated by comparing the center position APD-C of the alignment pad APD with the center position APP-C of the alignment polymer pattern APP. Therefore, the center position APP-C of the alignment polymer pattern APP may be designated as the cross-sectional analysis position of the alignment pad APD, so that the cross-sectional analysis with respect to the center position may be performed more accurately.

In addition, as described above, the same may be applied when the cross-sectional analysis of the signal pad PD is performed. Even if the polymer pattern PP is not directly observable on the back surface of the display panel DP, the center position of the polymer pattern PP of the signal pad PD may be measured, so that the cross-sectional analysis point may be designated more easily.

According to an embodiment of the present disclosure, the display device may inspect the alignment of the display panel and the bump by predicting the positions of the polymer patterns of the signal pad not directly observable on the back surface of the display panel, including the alignment polymer pattern spaced from the alignment pad. In addition, the alignment polymer pattern may be formed through the same process as the polymer pattern of the signal pad without an additional mask or an additional process.

According to an embodiment of the present disclosure, the electronic device may predict the positions of the signal pad and the polymer patterns of the signal pad by using the positions of the alignment pad and the alignment polymer patterns during the alignment inspection. Therefore, the cross-sectional analysis position with respect to the contact between the signal pad and the bump may be more easily designated.

According to an embodiment of the present disclosure, the alignment inspection method of the electronic device may predict the positions of the polymer patterns of the signal pad that not observable during the alignment inspection, by comparing the center position of the alignment polymer pattern with the center positions of the alignment bump and the alignment pad.

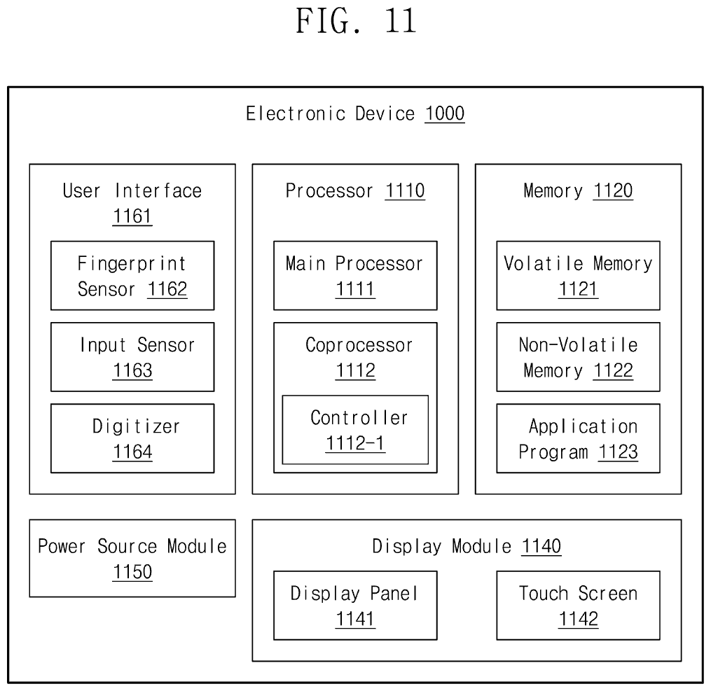

FIG. 11 is a diagram illustrating an electronic device according to an embodiment of the present invention. Referring to FIG. 11, the electronic device 1000 according to one embodiment of the present invention may output various information (e.g., images, text, music, etc.) through a display module 1140, which, for example, may correspond to the display device shown in FIG. 1. When a processor 1110 executes an application stored in a memory 1120, the display module 1140 may provide application information to a user through a display panel 1141.

In some embodiments, the electronic device 1000 may be configured as a smartphone, camera, smart TV, monitor, smartwatch, tablet, automotive display, or AR/VR headset. For example, the electronic device 1000 may be a smartphone including a touch-sensitive display area DA for interaction and a non-display area NDA including sensors and circuits for enhanced functionality. For example, the electronic device 1000 may be a television or monitor including a large display area DA for high-resolution video playback and a non-display area NDA incorporating driving circuits or connectivity modules for external inputs. For example, the electronic device 1000 may be a smartwatch including a display area DA optimized for compact and high-clarity visuals and a non-display area NDA integrating biometric sensors for health monitoring. In some cases, the electronic device 1000 be an AR/VR headset.

In some embodiments, memory 1120 may store information such as software codes for operating an application program 1123. The application program 1123 may include a software designed to execute specific tasks or provide functionality to a user. The application program 1123 may operate under the control of the processor 1110 and utilizes data stored in the memory 1120 to deliver a wide range of features, such as productivity tools, multimedia streaming and playback, file or mail deliveries or communication services. The application program 1123 interacts seamlessly with the user interface 1161 or touch screen 1142, allowing a user to launch, navigate, and utilize the program through user inputs such as touch, tap, gesture, or voice interaction.

Upon user selection of an application via touch screen 1142 or user interface 1161, the processor 1110 may execute the application program 1123 corresponding to the selected application retrieved from the memory 1120 to perform functionalities of the application. For example, when a user selects a camera application by tapping the icon (or a camera application icon) presented on the display panel 1141, the processor 1110 activates a camera module or the camera device. The processor 1110 may transmit image data corresponding to a captured image acquired through the camera module to the display module 1140. The display module 1140 may display an image corresponding to the captured image through the display panel 1141.

For example, the camera device may be configured to capture images of an alignment inspection area of the electronic device, where the alignment inspection area includes an alignment bump (e.g., ABP), an alignment pad (e.g., APD) bonded to the alignment bump, and an alignment polymer pattern (e.g., APP) that is spaced apart from the alignment pad; and the processor 1110 may be configured to: process the captured images to detect center positions of the alignment bump, the alignment pad, and the alignment polymer pattern; compare the detected center positions of the alignment bump and the alignment pad with the center position of the alignment polymer pattern; and determine presence of misalignment based on results of the compare.

As another example, when a user wishes to make a phone call, the user taps the telephone icon displayed on the display module 1140, the processor 1110 may execute a phone application program stored in the memory 1120. A telephone keypad may be presented on the display panel 1141 for the user to enter a phone number to call.

The memory 1120 may store instructions, that, when executed by the processor 1110, cause it to perform the above steps of processing, comparing, and determining misalignment.

As another example, the display module 1140 may be integrated into an electronic device 1000, such as a laptop computer, smart TV, or tablet. A user wishing to access a multimedia streaming application (e.g., to watch a music video or movie) can do so by tapping the corresponding icon. This action activates the application, allowing the user to view the streamed content.

The processor 1110 may include a main processor 1111 and an auxiliary or coprocessor 1112. The main processor 1111 may include a central processing unit (CPU). The main processor 1111 may further include one or more of a graphics processing unit (GPU), a communication processor (CP), and an image signal processor (ISP).

The coprocessor 1112 may include a controller 1112-1. The controller 1112-1 may include an interface conversion circuit and a timing control circuit. The controller 1112-1 may receive an image signal from the main processor 1111, convert the data format of the image signal to match the interface specifications with the display module 1140, and output image data. The controller 1112-1 may output various control signals to drive the display module 1140. For example, the controller 1112-1 may drive the display module 1140 to display the icon on the display screen suitable for selection by a user to cause execution of an application program 1123.

The memory 1120 may store one or more application programs 1123 and various data used by at least one component (for example, the processor 1110 or the user interface 1161) of the electronic device 1000 and input data or output data for commands related thereto. For example, a camera application program, a GPS application program, an augmented reality and virtual reality application program, and other application programs that can be executed by the processor 1110 upon selection of corresponding icons presented on the display screen (or display panel 1141) via the touch screen 1142 or user interface 1161 by the user. In addition, various setting data corresponding to user settings may be stored in the memory 1120. The memory 1120 may include volatile memory 1121 and non-volatile memory 1122.

The processor 1110 may provide an output signal to the user interface 1161 based on the determination of misalignment, where the output signal can be used to alert operators or activate further inspection or correction processes.

The display module 1140 may output visual information (images) to the user. The display module 1140 may include the display panel 1141, a gate driver, the source driver, a voltage generation circuit, and a touch screen 1142. The display module 1140 may further include a window, a chassis, and a bracket to protect the display panel 1141. The display module 1140 may include at least a part of the configuration of the display device shown in FIG. 1.

The user interface 1161 serves as the interaction medium between a user and the electronic device 1000. The user interface 1161 may detect an input by a part (e.g., finger) of a user's body or an input by a pen or a mouse, and generate an electric signal or data value corresponding to the input. The user interface 1161 includes the fingerprint sensor 1162, the input sensor 1163, and a digitizer 1164.

The fingerprint sensor 1162 may sense a fingerprint for biometric recognition of the user and may also measure one or more biological signals such as blood pressure, moisture, or body mass.

The input sensor 1163 may sense user interactions including touch, tap, gesture, motion, spoken command, and eye movement. The input sensor 1163 includes optical sensors for image capture, eye tracking, or motion and gesture detection. Optical sensors may be infrared or semiconductor photodetectors. The input sensor 1163 includes audio and acoustic sensors, which may be MEMS microphones for voice recognition or sound-based interaction. The audio and acoustic sensors can be installed as part of the user interface 1161 or embedded in the display panel 1141.

The digitizer 1164 may generate a data value corresponding to coordinate information of input by a pen or a mouse to control movement of an onscreen cursor. The digitizer 1164 may generate the amount of change in electromagnetic due to the input as the data value. The digitizer may detect an input by a passive pen or transmit and receive data with an active pen or a remote.

At least one of the fingerprint sensor 1162, the input sensor 1163, or the digitizer 1164 may be implemented as a sensor layer formed on the top layer of the display panel 1141 through a continuous process with a process of forming elements (for example, the light emitting element, the transistor, and the like) included in the display panel 1141.

In addition, the user interface 1161 may further include, for example, a gesture sensor, a gyro sensor that senses rotational movements, an acceleration sensor to track translational movement, a grip sensor, a pressure sensor, a proximity sensor, a color sensor, an infrared (IR) emitter and camera sensor for tracking gaze direction and eye movements, a temperature sensor, or a light sensor. For example, the gyro sensor, acceleration sensor, and infrared emitter and camera may be particularly suitable for AR/VR headset functions.

The touch screen 1142 includes touch sensors embedded in semiconductor layers of the display panel 1141 to sense pressure applied to the top layer (screen) of the display panel 1141. The touch sensors can be a capacitive or a resistive type. The touch screen 1142 may serve as the primary interface for the user to select and navigate applications, control, and interact with the electronic device 1000.

The display panel 1141 (or display) may include a liquid crystal display panel, an organic light emitting display panel, or an inorganic light emitting display panel, and the type of the display panel 1141 is not particularly limited. The display panel 1141 may be of a rigid type or a flexible type that can be rolled or folded. The display module 1140 may further include a supporter, bracket, heat dissipation member, and the like that support the display panel 1141. The display panel 1141 may include the display unit shown in FIG. 1.

The power source module 1150 may supply power to the components of the electronic device 1000. The power source module 1150 may include a battery that charges the power source voltage. The battery may include a non-rechargeable primary battery or a rechargeable secondary battery or fuel cell. The power source module 1150 may include a power management integrated circuit (PMIC). The PMIC may supply optimized power source to each of the components described above including the display module 1140.

Although the present disclosure has been described above with reference to embodiments thereof, it will be understood by those skilled in the art that various modifications, and substitutions are possible, without departing from the spirit and the technical scope of the present disclosure as set forth in the claims below. Accordingly, the technical scope of the present disclosure is not limited to the detailed description of this specification.

What is claimed is:

1. A display device comprising:
a pixel;
a signal line electrically connected to the pixel;
a signal pad electrically connected to the signal line;
an alignment pad spaced apart from the signal pad; and
an alignment polymer pattern spaced apart from the alignment pad, and wherein the signal pad comprises:
a first conductive pattern electrically connected to an end of the signal line;
a polymer pattern disposed on the first conductive pattern; and
a second conductive pattern disposed on the polymer pattern.

2. The display device of claim 1, wherein the alignment polymer pattern and the polymer pattern include a same material.

3. The display device of claim 1, wherein the alignment pad and the alignment polymer pattern are arranged on a same insulating layer.

4. The display device of claim 1, wherein on a plane, a length of the alignment pad is greater than or equal to 30 micrometers (μm) and is shorter than a length of the signal pad.

5. The display device of claim 1, wherein on a plane, a width of the alignment pad is the same as a width of the signal pad.

6. The display device of claim 1, wherein the alignment pad is provided as a plurality of alignment pads, and
on a plane, the plurality of alignment pads extend in a first direction and are spaced apart from one another in a second direction intersecting the first direction.

7. The display device of claim 6, wherein the polymer pattern is provided as a plurality of polymer patterns, and
on the plane, the plurality of polymer patterns are spaced apart from each other in the first direction.

8. The display device of claim 1, wherein, on a plane, the alignment polymer pattern is spaced apart from the alignment pad in a first direction,
wherein the alignment pad and the alignment polymer pattern are spaced apart from the signal pad in a second direction intersecting the first direction, and
wherein a center of the alignment pad and a center of the alignment polymer pattern are aligned within the second direction.

9. The display device of claim 1, wherein, on a plane, the alignment polymer pattern is spaced apart from the alignment pad in a first direction,
wherein the alignment pad and the alignment polymer pattern are spaced apart from the signal pad in a second direction intersecting the first direction, and
wherein an additional polymer pattern is further disposed on the alignment pad, and
wherein a separation distance between the additional polymer pattern and the polymer pattern of the signal pad in the second direction is the same as a separation distance between the alignment polymer pattern and the polymer pattern of the signal pad in the second direction.

10. The display device of claim 1, wherein the signal pad is provided as a plurality of signal pads,
wherein the plurality of signal pads define a plurality of pad rows,
wherein each of the plurality of pad rows extends in a first direction and is arranged in a second direction intersecting the first direction, and
wherein the signal pads extend in a first diagonal direction intersecting the first direction and the second direction.

11. The display device of claim 10, wherein the alignment pad is provided as a plurality of alignment pads,
wherein one of the plurality of pad rows includes an alignment inspection area in which the signal pad is not disposed,
wherein the plurality of alignment pads are disposed within the alignment inspection area, and
wherein the alignment pads extend in the first diagonal direction.

12. An electronic device comprising:
a display device including a display area for display an image and a non-display area adjacent to the display area; and
an electronic component disposed in the non-display area and electrically connected to the display device, and
wherein the electronic component includes a signal bump and an alignment bump, and
wherein the display device comprises:
a pixel disposed in the display area;
a signal pad disposed in the non-display area and corresponding to the signal bump;
an alignment pad disposed in the non-display area and corresponding to the alignment bump;
an alignment polymer pattern disposed in the non-display area and spaced apart from the alignment pad; and
a signal line disposed in the display area and the non-display area and electrically connecting the pixel to the signal pad.

13. The electronic device of claim 12, wherein the signal pad includes a conductive pattern and a polymer pattern protruding toward the signal bump.

14. The electronic device of claim 13, wherein the polymer pattern and the alignment polymer pattern include a same material.

15. The electronic device of claim 12, wherein the alignment pad has a smaller area than the signal pad.

16. The electronic device of claim 12, wherein the alignment pad exposes a portion of the alignment bump.

17. The electronic device of claim 12, wherein, on a plane, the alignment polymer pattern is spaced apart from the alignment pad in a first direction,
wherein the alignment pad and the alignment polymer pattern are spaced apart from the signal pad in a second direction intersecting the first direction,
wherein an additional polymer pattern is further disposed on the alignment pad, and
wherein a separation distance between the additional polymer pattern and the polymer pattern of the signal pad in the second direction is the same as a separation distance between the alignment polymer pattern and the polymer pattern of the signal pad in the second direction.

18. An inspection method for alignment of an electronic device, comprising:
detecting an alignment inspection area of the electronic device including an alignment bump, an alignment pad bonded to the alignment bump, and an alignment polymer pattern non-overlapping with the alignment pad;
detecting a center position of the alignment bump;
detecting a center position of the alignment pad;
detecting a center position of the alignment polymer pattern; and
comparing at least one of the center position of the alignment bump and the center position of the alignment pad with the center position of the alignment polymer pattern.

19. The inspection method of claim 18, wherein the electronic device further includes an additional polymer pattern overlapping the alignment pad, and further comprising calculating a center position of the additional polymer pattern by comparing the center position of the alignment bump with the center position of the alignment polymer pattern.

20. The inspection method of claim 18, wherein the electronic device further includes an additional polymer pattern overlapping the alignment pad, and further comprising calculating a center position of the additional polymer pattern by comparing the center position of the alignment pad with the center position of the alignment polymer pattern.
